(19) United States
(12) Patent Application Publication
(10) Pub. No.: US 2017/0278960 A1
(43) Pub. Date: Sep. 28, 2017

(54) SEMICONDUCTOR DEVICE AND MANUFACTURING METHOD THEREOF

(71) Applicant: DELTA ELECTRONICS, INC., Taoyuan City (TW)

(72) Inventors: Ching-Chuan SHIUE, Taoyuan City (TW); Po-Chin PENG, Taoyuan City (TW); Wen-Chia LIAO, Taoyuan City (TW); Shih-Peng CHEN, Taoyuan City (TW)

(21) Appl. No.: 15/080,544

(22) Filed: Mar. 24, 2016

(51) Int. Cl. H01L 29/778; H01L 29/205; H01L 29/10; H01L 29/207; H01L 29/66; H01L 21/266; H01L 21/265; H01L 21/324; H01L 23/31; H01L 29/20; H01L 21/02

(52) U.S. Cl. CPC H01L 29/7787; H01L 29/2003; H01L 29/205; H01L 29/1058; H01L 29/207; H01L 21/0254; H01L 21/266; H01L 21/26546; H01L 21/3245; H01L 23/3171; H01L 29/66462

(57) ABSTRACT

A semiconductor device including a substrate, a plurality of III-nitride semiconductor layers, a source electrode, a gate electrode, a drain electrode, and a doped layer. The III-nitride semiconductor layers are disposed on the substrate. A two dimensional electron gas (2DEG) channel is formed in the III-nitride semiconductor layers. The source electrode, the gate electrode, and the drain electrode are disposed on the III-nitride semiconductor layers. The gate electrode is located between the source electrode and the drain electrode. The source electrode and the drain electrode are electrically connected to the 2DEG channel. A lateral direction is defined from the source electrode to the drain electrode. The doped layer is disposed between the gate electrode and the III-nitride semiconductor layers. The doped layer includes a plurality of dopants, and a concentration of the dopants varies along the lateral direction.

### BACKGROUND

Field of Disclosure

The present disclosure relates to a semiconductor device. More particularly, the present disclosure relates to a high electron mobility transistor (HEMT).

Description of Related Art

A nitride semiconductor has high electric breakdown field and high electron saturation velocity. Thus, the nitride semiconductor is expected to be a semiconductor material for semiconductor devices having high breakdown voltage and low on-state resistance. Many of the conventional semiconductor devices using the nitride related materials may have heterojunctions. The heterojunction is configured with two types of nitride semiconductors having different bandgap energies from each other and is able to generate a two-dimensional electron gas layer (2DEG layer) near the junction plane. The semiconductor devices having the heterojunction may achieve a low on-state resistance. These types of semiconductor devices are called high electron mobility transistors (HEMT).

### SUMMARY

An aspect of the present disclosure is to provide a semiconductor device including a substrate, a plurality of III-nitride semiconductor layers, a source electrode, a gate electrode, a drain electrode, and a doped layer. The III-nitride semiconductor layers are disposed on the substrate. A two dimensional electron gas (2DEG) channel is formed in the III-nitride semiconductor layers. The source electrode, the gate electrode, and the drain electrode are disposed on the III-nitride semiconductor layers. The gate electrode is located between the source electrode and the drain electrode. The source electrode and the drain electrode are electrically connected to the 2DEG channel. A lateral direction is defined from the source electrode to the drain electrode. The doped layer is disposed between the gate electrode and the III-nitride semiconductor layers. The doped layer includes a plurality of dopants, and a concentration of the dopants varies along the lateral direction.

In some embodiments, the concentration of the dopants decreases along the lateral direction.

In some embodiments, the concentration of the dopants increases along the lateral direction.

In some embodiments, the doped layer includes a first portion, a second portion, and a third portion arranged along the lateral direction. The third portion is disposed between the first portion and the second portion. The concentration of the dopants of the third portion is higher than the concentration of the dopants of the first portion and the concentration of the dopants of the second portion.

In some embodiments, the concentration of the dopants of the third portion is substantially uniform.

In some embodiments, the doped layer includes a first portion, a second portion, and a third portion arranged along the lateral direction. The third portion is disposed between the first portion and the second portion. The concentration of the dopants of the third portion is lower than the concentration of the dopants of the first portion and the concentration of the dopants of the second portion.

In some embodiments, the concentration of the dopants of the third portion is substantially uniform.

In some embodiments, the dopants of the doped layer comprise Mg, C, Ca, Fe, Cr, V, Mn, Be, or combinations thereof.

In some embodiments, the doped layer is made of InₓAl_{y}Ga_{1-x-y}N, wherein—x+y≦1.

Another aspect of the present disclosure is to provide a method for manufacturing a semiconductor device including forming a plurality of III-nitride semiconductor layers on a substrate. A doped layer is formed on the III-nitride semiconductor layers. The doped layer includes a plurality of dopants, and a concentration of the dopants varies along a lateral direction. A source electrode and a drain electrode are formed on the III-nitride semiconductor layers. The source electrode and the drain electrode are arranged along the lateral direction, and the doped layer is disposed between the source electrode and the drain electrode. A gate electrode is formed on the doped layer.

In some embodiments, the forming the doped layer includes forming a semiconductor layer on the III-nitride semiconductor layers. A mask layer is formed to cover the semiconductor layer. The mask layer is patterned to expose at least a portion of the semiconductor layer. The dopants are—implanted into the semiconductor layer to form the doped layer.

In some embodiments, the patterned mask layer is removed after the implantation is performed. The doped layer is annealed.

In some embodiments, the mask layer is made of photoresist, SiO₂, SiNₓ, or metal.

In some embodiments, the forming the doped layer includes forming a semiconductor layer on the III-nitride semiconductor layers. A mask layer is formed to cover the semiconductor layer. The mask layer is patterned to expose at least a portion of the semiconductor layer. The semiconductor layer is annealed to form the doped layer.

In some embodiments, the mask layer is made of metal.

In some embodiments, the forming the doped layer includes forming a semiconductor layer on the III-nitride semiconductor layers. A mask layer is formed to cover the semiconductor layer. The mask layer is patterned to form at least one opening to expose at least a portion of the semiconductor layer. A doping material is formed in the opening. The semiconductor layer is annealed to diffuse the dopants to form the doped layer.

In some embodiments, the dopant material is made of metal.

In some embodiments, the dopants of the doped layer comprise Mg, C, Ca, Fe, Cr, V, Mn, Be, or combinations thereof.

In some embodiments, the doped layer is made of InₓAl_{y}Ga_{1-x-y}N, wherein x+y≦1.

In some embodiments, the method further includes forming a passivation layer on the III-nitride semiconductor layers to cover the doped layer. A portion of the passivation layer on the doped layer is removed.

### BRIEF DESCRIPTION OF THE DRAWINGS

FIGS. 1A to 1H are cross-sectional views of a method for manufacturing a semiconductor device at different stages according to some embodiments of the present disclosure;

FIGS. 2A and 2B are schematic graphs of concentrations of the dopants along a lateral direction of FIG. 1E;

FIGS. 3A to 3C are cross-sectional views of the semiconductor devices at the stage of FIG. 1C according to some other embodiments;

FIGS. 4A to 4F are schematic graphs of concentrations of the dopants along a lateral direction;

FIGS. 5A to 5D are cross-sectional views of a method for manufacturing a semiconductor device at different stages according to some embodiments of the present disclosure;

FIGS. 6A to 6C are cross-sectional views of the semiconductor devices at the stage of FIG. 5B according to some embodiments;

FIGS. 7A to 7E are cross-sectional views of a method for manufacturing a semiconductor device at different stages according to some embodiments of the present disclosure;

FIGS. 8A to 8C are cross-sectional views of the semiconductor devices at the stage of FIG. 7C according to some embodiments; and

FIG. 9 is a graph of simulated gate-drain capacitances versus source-drain voltage (Vsd) of semiconductor device having a uniform and non-uniform doped layer.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

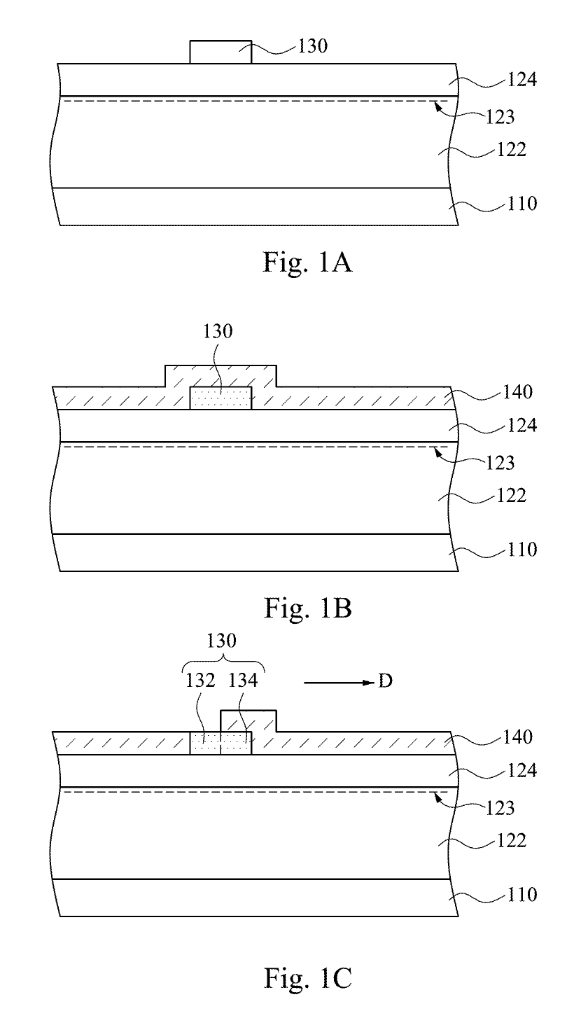

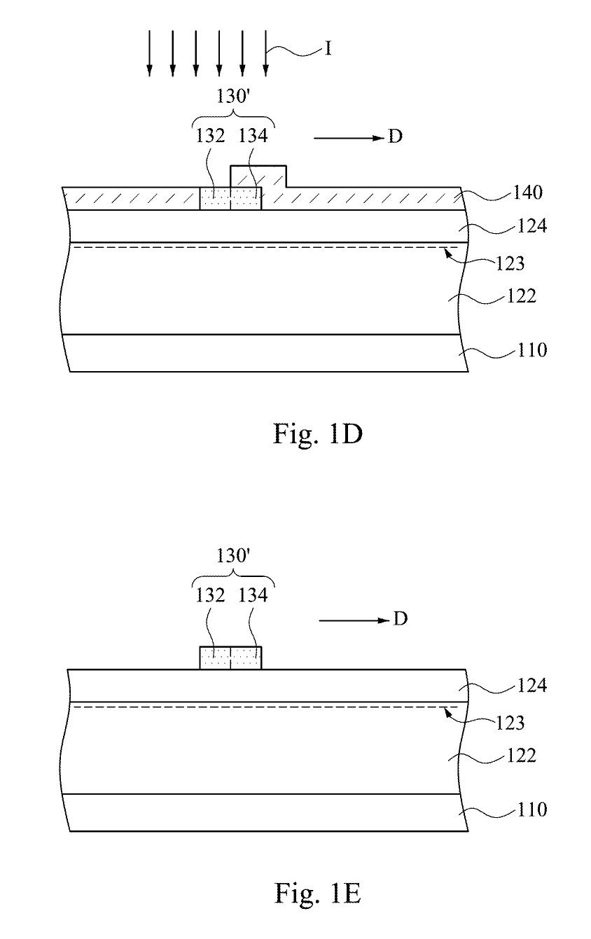

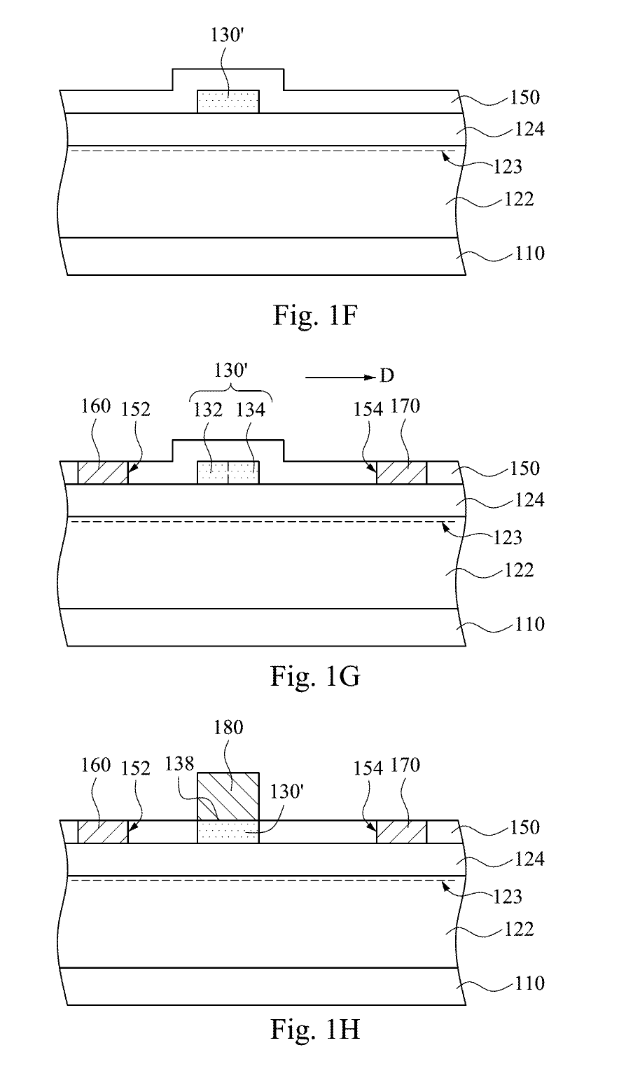

FIGS. 1A to 1H are cross-sectional views of a method for manufacturing a semiconductor device at different stages according to some embodiments of the present disclosure. Reference is made to FIG. 1A. A substrate 110 is provided. The substrate 110 can be any substrate suitable for the purposes discussed herein, such as silicon carbide, sapphire, silicon, aluminum nitride, gallium nitride, or zinc oxide. Although not shown in the FIG. 1A, a transition layer or a nucleation layer can be formed on the substrate 110 to provide a base layer for proper epitaxial growth of device profile layers (i.e., III-nitride semiconductor layers mentioned in the next paragraph). The nucleation layer is specific to the type of substrate used.

A plurality of III-nitride semiconductor layers are formed on the substrate 110. In some embodiments, the III-nitride semiconductor layers include a buffer layer 122 and a barrier layer 124. The buffer layer 122 is disposed on the substrate 110, and the barrier layer 124 is disposed on the buffer layer 122. The buffer layer 122 can provide a uniform crystal structure for epitaxial deposition, and thus can be optionally included for improved device characteristics. In some embodiments, the buffer layer 122 can be a nitride based material to provide good adhesion for the layers formed thereon and also solve issues of lattice mismatch, but the present disclosure is not limited in this respect. The buffer layer 122 can be a single layer such as an InₓAl_{y}Ga_{1-x-y}N layer, where x+y≦1, or can be a composite layer. The barrier layer 124 can be made of materials having a larger band gap than the buffer layer 122, such as InₓAl_{y}Ga_{1-x-y}N, where x+y≦1. In some embodiments, the barrier layer 124 can be doped or undoped. A charge accumulates at the interface between the buffer layer 122 and the barrier layer 124 and creates a two dimensional electron gas (2DEG) 123. The 2DEG 123 has very high electron mobility which gives the semiconductor device a very high transconductance at high frequencies.

Subsequently, a semiconductor layer 130 is formed on the barrier layer 124. For example, a semiconductor film (not shown) is formed (or deposited) on the barrier layer 124, and then the semiconductor film is patterned to be the semiconductor layer 130. In some embodiments, the semiconductor layer 130 is made of InₓAl_{y}Ga_{1-x-y}N, where x+y≦1. In some embodiments, the semiconductor layer 130 is made of GaN, and the claimed scope of the present disclosure is not limited in this respect.

Reference is made to FIG. 1B. A mask layer 140 is formed to cover the semiconductor layer 130 and the barrier layer 124. The mask layer 140 can be a resist layer, which is also referred to as a photoresist layer, photosensitive layer, imaging layer, patterning layer, or radiation sensitive layer. The mask layer 140 includes a positive-type resist material, a negative-type resist material, other type material, or combinations thereof. The mask layer 140 can be formed on the semiconductor layer 130 and the barrier layer 124 by using a deposition process. However, in some other embodiments, the mask layer 140 may be made of SiO₂, SiNₓ, or metal.

Reference is made to FIG. 1C. The mask layer 140 is patterned to expose at least a portion of the semiconductor layer 130. For example, in FIG. 1C, the semiconductor layer 130 includes a first portion 132 and a second portion 134 arranged along a lateral direction D, and the mask layer 140 exposes the first portion 132 of the semiconductor layer 130. The mask layer 140 can be patterned by using a lithography process. The lithography process includes resist soft baking, mask aligning, exposure, post-exposure baking, developing the resist, rinsing, drying (for example, hard baking), other suitable processes, or combinations thereof. Alternatively, the lithography process is implemented or replaced by other methods, such as maskless lithography, electron-beam writing, or ion-beam writing. In some embodiments, the lithography process implements an etching process, such as a dry etching, wet etching, other etching method, or combinations thereof.

Reference is made to FIG. 1D. An (ion) implantation process I is performed. The implantation process implants dopants into the exposed portion (i.e., the first portion 132) of the semiconductor layer 130 (see FIG. 1C) to form a doped layer 130′. Dosage, energy, and depth of the implantation are dependent upon the ion to be implanted the semiconductor layer 130. In some embodiments, the dopants are acceptor type dopants, such as Mg, C, Ca, Fe, Cr, V, Mn, Be, or combinations thereof, such that the doped layer 130′ is a p-type layer.

Reference is made to FIG. 1E. The mask layer 140 (see FIG. 1D) is removed. In some embodiments, the mask layer 140 can be removed by performing a wet etching process, a dry etching process, or combinations thereof. Subsequently, an annealing process is performed to the doped layer 130′. The dopants of the doped layer 130′ diffuse during the annealing process, and the concentration of the dopants varies along the lateral direction D.

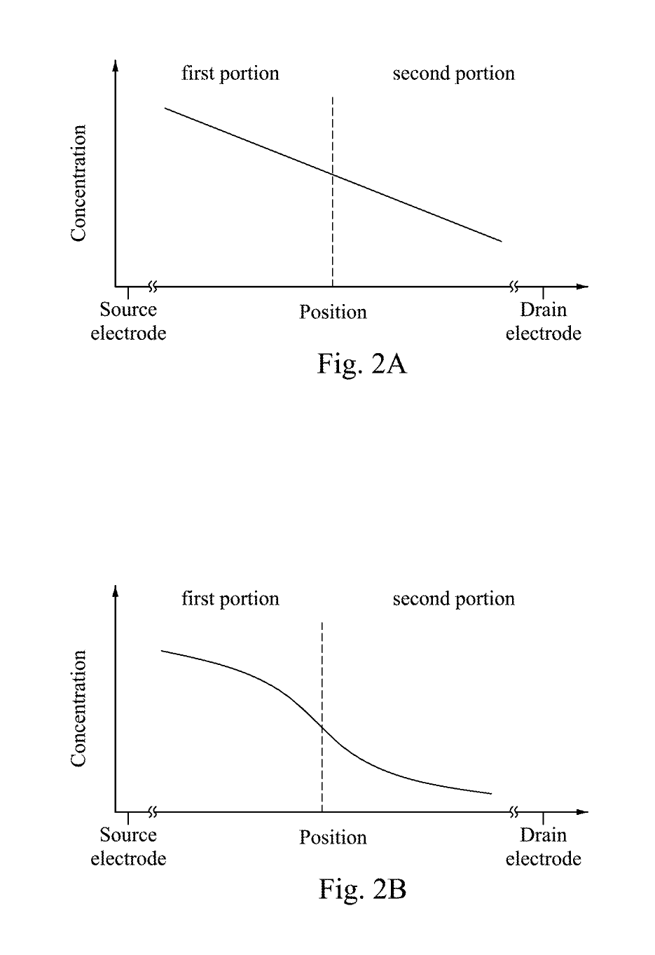

FIGS. 2A and 2B are schematic graphs of concentrations of the dopants along the lateral direction D of FIG. 1E. Reference is made to FIGS. 1E, 2A, and 2B. Since the dopants are implanted into the first portion 132, the concentration of the dopants of the first portion 132 is higher than the concentration of the dopants of the second portion 134. That is, the concentration of the dopants decreases along the lateral direction D. Furthermore, as shown in FIGS. 2A and 2B, the concentration curve can be adjusted according to the annealing conditions.

Reference is made to FIG. 1F. A passivation layer 150 is formed to cover the doped layer 130′ and the barrier layer 124. The passivation layer 150 may be made of dielectric materials, such as silicon nitride or silicon oxynitride.

Reference is made to FIG. 1G. The passivation layer 150 is patterned to form a first opening 152 and a second opening 154, and the doped layer 130′ is disposed between the first opening 152 and the second opening 154. The first opening 152 and the second opening 154 are arranged along the lateral direction D. The first opening 152 and the second opening 154 respectively expose portions of the barrier layer 124.

Subsequently, a source electrode 160 and a drain electrode 170 are respectively formed in the first opening 152 and the second opening 154. That is, the source electrode 160 and the drain electrode 170 are arranged along the lateral direction D. In FIG. 1G, the first portion 132 of the doped layer 130′ is located near the source electrode 160 and away from the drain electrode 170, and the second portion 134 of the doped layer 130′ is located near the drain electrode 170 and away from the source electrode 160. In some embodiments, the source electrode 160 and the drain electrode 170 are made of conductive materials, such as metal, and the source electrode 160 and the drain electrode 170 are electrically connected to the 2DEG 123.

Reference is made to FIG. 1H. The passivation layer 150 is further patterned to expose the top surface 138 of the doped layer 130′. Subsequently, a gate electrode 180 is formed on the doped layer 130′. In some embodiments, the gate electrode 180 is made of conductive materials, such as metal. The passivation layer 150 can prevent the current leakage.

In FIG. 1H, the semiconductor device is an enhancement-mode (E-mode) high-electron-mobility transistor (HEMT). The 2DEG 123 allows current to flow between the source electrode 160 and the drain electrode 170. The voltage applied to the gate electrode 180 controls the number of electrons of the 2DEG 123 under the gate electrode 180, and thus controls the total electron flow. The doped layer 130′ depletes the underneath 2DEG 123. The concentration of the dopants of the doped layer 130′ affects the electron density of the 2DEG 123. More specifically, the electron density of the 2DEG 123 decreases as the concentration of the dopants of the doped layer 130′ increases. Therefore, in FIG. 1H, the electron density of the 2DEG 123 under the doped layer 130′ is not uniform. The electron density of the 2DEG 123 under the first portion 132 (see FIG. 1G) of the doped layer 130′ is lower than the electron density of the 2DEG 123 under the second portion 134 (see FIG. 1G) of the doped layer 130′. With such configuration, the gate-source capacitance (Cgs, the capacitance between the gate electrode 180 and the source electrode 160) can be modified, as well as the gate-drain capacitance (Cgd, the capacitance between the gate electrode 180 and the drain electrode 170).

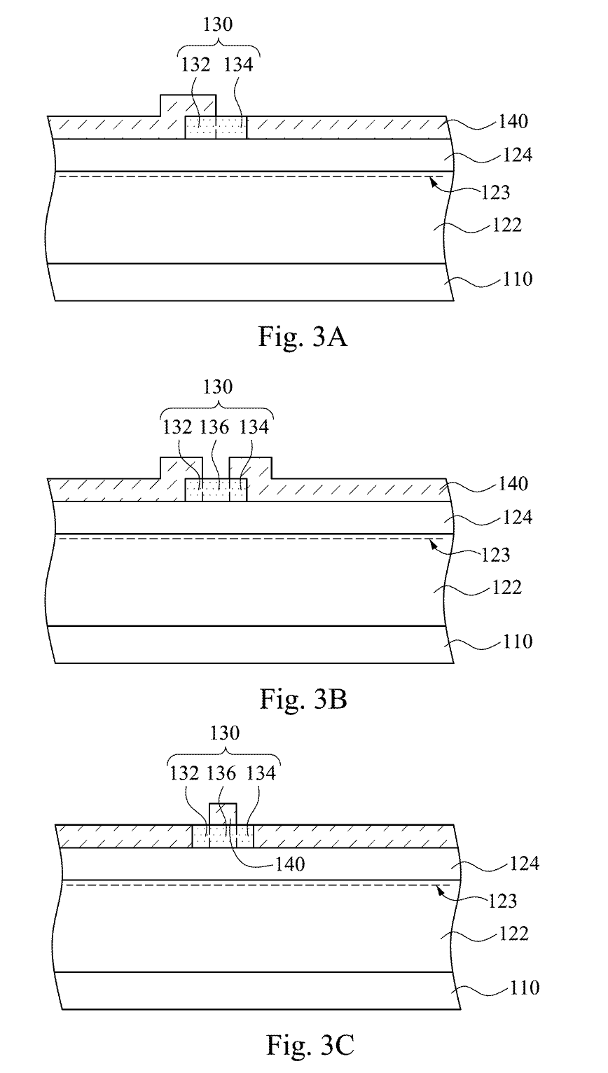

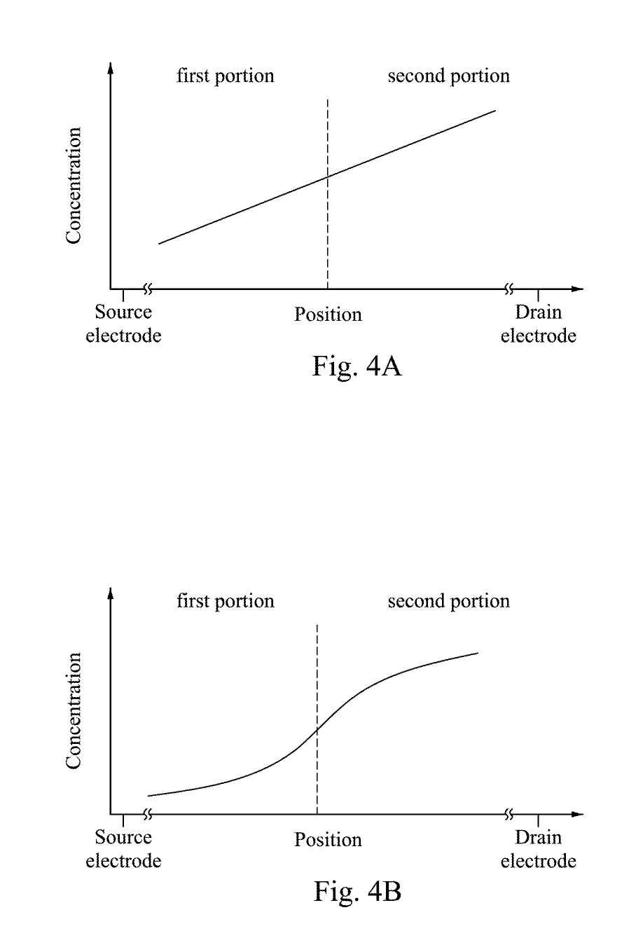

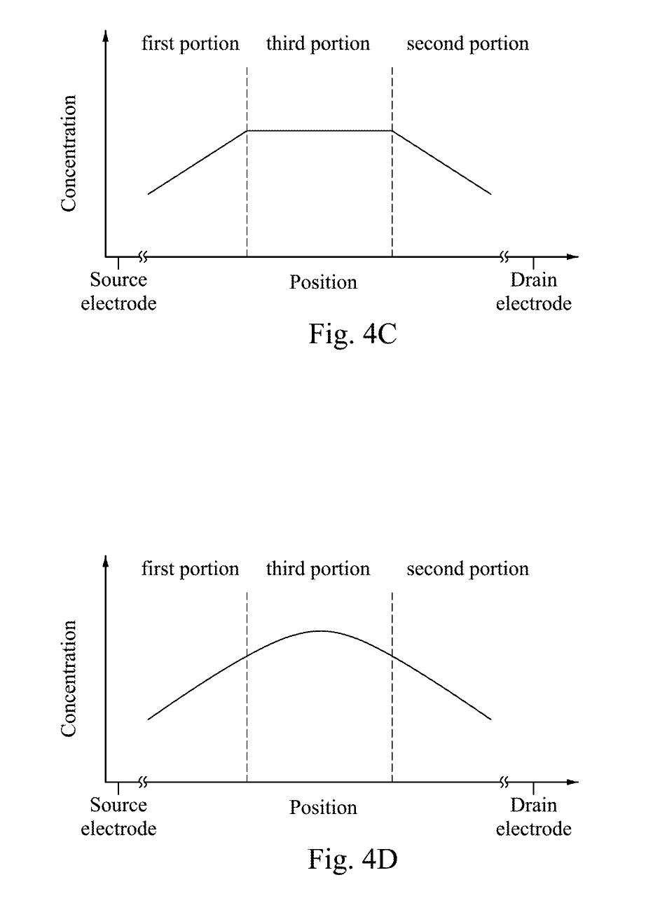

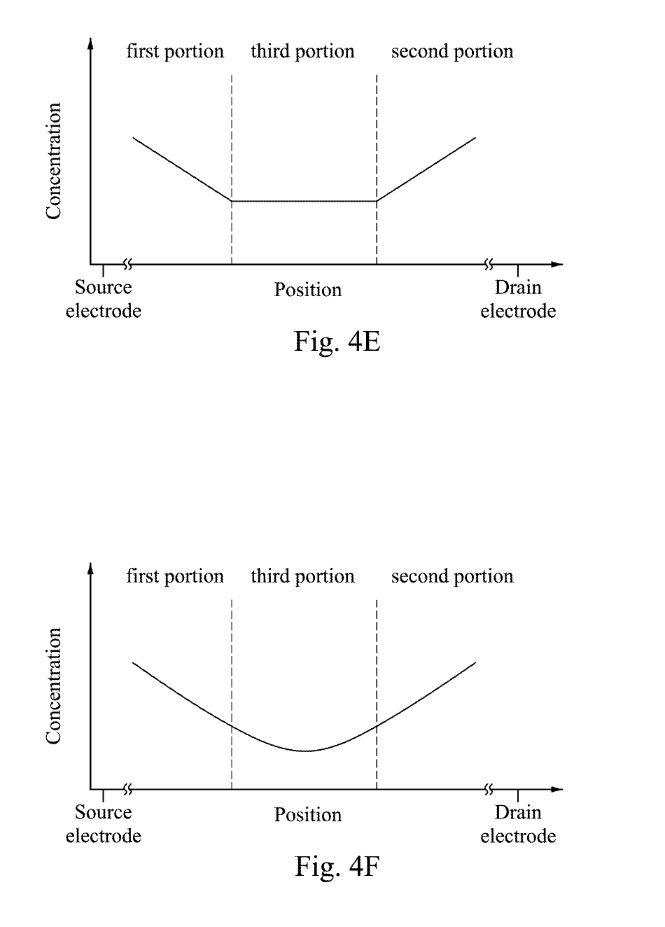

In some other embodiments, the mask layer 140 (see FIG. 1C) have different patterns to form the doped layer 130′ with different concentration distributions of the dopants. FIGS. 3A to 3C are cross-sectional views of the semiconductor devices at the stage of FIG. 1C according to some other embodiments. In FIG. 3A, the mask layer 140 covers the first portion 132 of the semiconductor layer 130 and exposes the second portion 134 of the semiconductor layer 130. After the implantation and annealing processes (see FIGS. 1D and 1E), the concentration of the dopants of the doped layer can be depicted as shown in FIG. 4A or 4B. In FIG. 3B, the semiconductor layer 130 further includes a third portion 136 disposed between the first portion 132 and the second portion 134. The mask layer 140 covers the first portion 132 and the second portion 134 and exposes the third portion 136. After the implantation and annealing processes (see FIGS. 1D and 1E), the concentration of the dopants of the doped layer can be depicted as shown in FIG. 4C or 4D. The concentration of the dopants of the third portion 136 can be substantially uniform (FIG. 4C) or non-uniform (FIG. 4D). In FIG. 3C, the mask layer 140 covers the third portion 136 and exposes the first portion 132 and the second portion 134. After the implantation and annealing processes (see FIGS. 1D and 1E), the concentration of the dopants of the doped layer can be depicted as shown in FIG. 4E or 4F. The concentration of the dopants of the third portion 136 can be substantially uniform (FIG. 4E) or non-uniform (FIG. 4F).

The patterns of the mask layer 140 of the aforementioned embodiments are illustrative, and should not limit the claimed scope of the present disclosure. An embodiment falls within the claimed scope as long as the concentration of the dopants of the doped layer 130′ varies along the lateral direction D, such that the Cgs and Cgd can be adjusted.

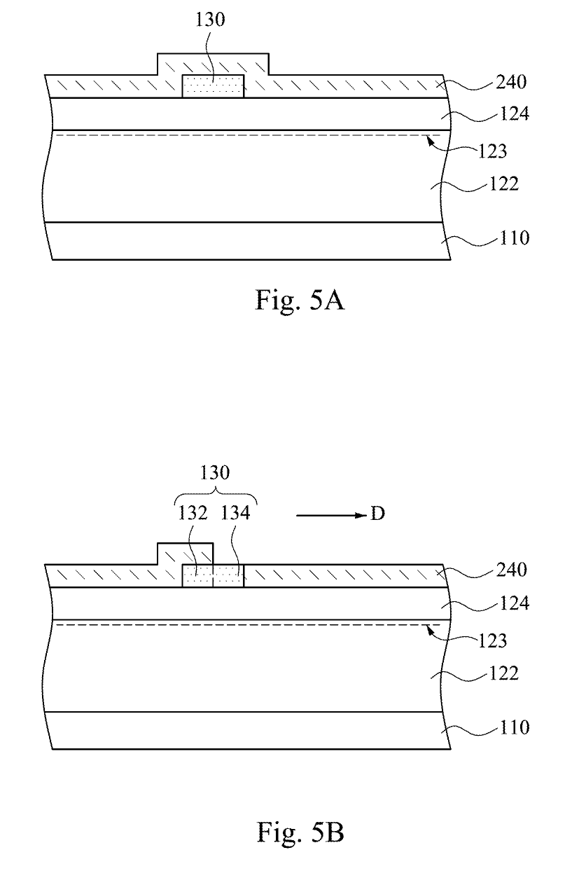

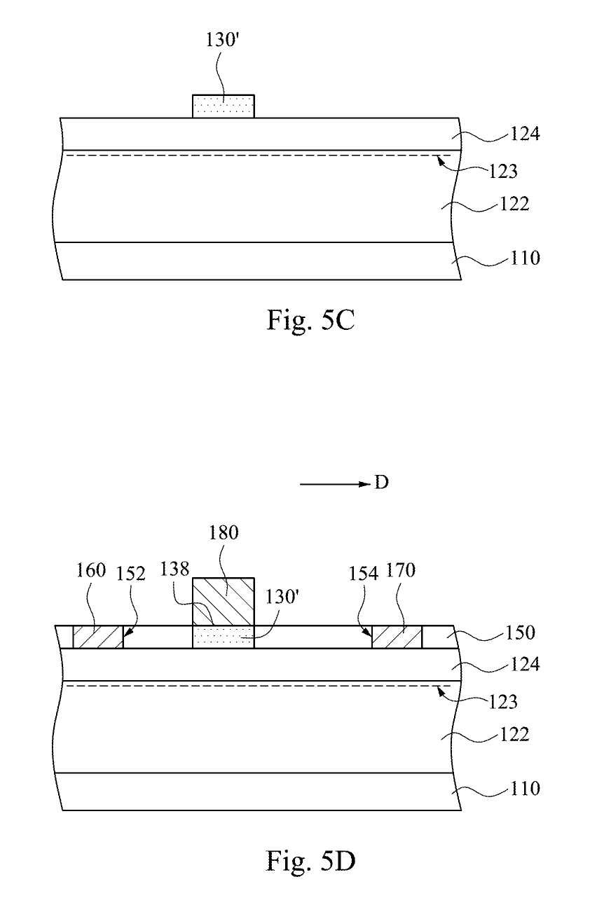

FIGS. 5A to 5D are cross-sectional views of a method for manufacturing a semiconductor device at different stages according to some embodiments of the present disclosure. Reference is made to FIG. 5A. The manufacturing process of FIG. 1A is performed in advance. Since the relevant manufacturing details are all the same as FIG. 1A, and, therefore, a description in this regard will not be repeated hereinafter. Subsequently, a mask layer 240 is formed to cover the semiconductor layer 130. In some embodiments, the mask layer 240 may be made of C or metal, such as Mg, Ca, Fe, Cr, V, Mn, Be, or combinations thereof.

Reference is made to FIG. 5B. The mask layer 240 is patterned to expose at least a portion of the semiconductor layer 130. For example, in FIG. 5B, the mask layer 240 exposes the second portion 134 of the semiconductor layer 130. The mask layer 240 can be patterned by using a lithography process. Alternatively, the lithography process is implemented or replaced by other methods, such as maskless lithography, electron-beam writing, or ion-beam writing. In some embodiments, the lithography process implements an etching process, such as a dry etching, wet etching, other etching method, or combinations thereof.

An annealing process is performed to the semiconductor layer 130 to form the doped layer 130′ (see FIG. 5C). The annealing process is implemented to break the bonds (such as Mg-H bonds) in the semiconductor layer 130 and increase the dopant concentration thereof. Since the mask layer 240 covers the first portion 132 and leaves the second portion 134 uncovered, the concentration of the dopants of the doped layer 130′ varies along the lateral direction D. For example, the concentration curve may be depicted as shown in FIG. 4A or 4B.

Reference is made to FIG. 5C. The mask layer 240 (see FIGS. 5B) is removed. In some embodiments, the removing process implements an etching process, such as a dry etching, wet etching, other etching method, or combinations thereof.

Reference is made to FIG. 5D. A passivation layer 150 is formed to cover the doped layer 130′ and the barrier layer 124. The passivation layer 150 is patterned to form a first opening 152 and a second opening 154. A source electrode 160 and a drain electrode 170 are respectively formed in the first opening 152 and the second opening 154. The passivation layer 150 is further patterned to expose the top surface 138 of the doped layer 130′. A gate electrode 180 is formed on the doped layer 130′. Since the abovementioned processes are similar to the processes shown in FIGS. 1F to 1H, a description in this regard will not be repeated hereinafter.

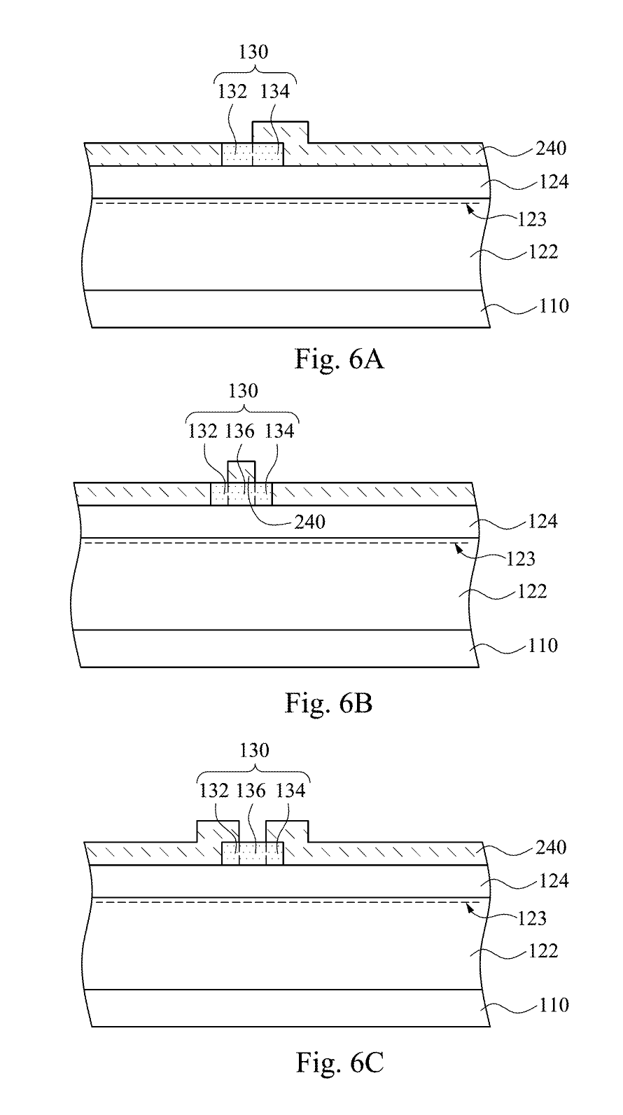

Moreover, in some other embodiments, the mask layer 240 (see FIG. 5B) have different patterns to form the doped layer 130′ with different concentration distributions of the dopants. FIGS. 6A to 6C are cross-sectional views of the semiconductor devices at the stage of FIG. 5B according to some embodiments. In FIG. 6A, the mask layer 240 covers the second portion 134 of the semiconductor layer 130 and exposes the first portion 132 of the semiconductor layer 130. After the annealing process, the concentration of the dopants of the doped layer can be depicted as shown in FIG. 2A or 2B. In FIG. 6B, the mask layer 240 covers the third portion 136 and exposes the first portion 132 and the second portion 134. After the annealing process, the concentration of the dopants of the doped layer can be depicted as shown in FIG. 4E or FIG. 4F. The concentration of the dopants of the third portion 136 can be substantially uniform (FIG. 4E) or non-uniform (FIG. 4F). In FIG. 6C, the mask layer 240 covers the first portion 132 and the second portion 134 and exposes the third portion 136. After the annealing process, the concentration of the dopants of the doped layer can be depicted as shown in FIG. 4C or 4D. The concentration of the dopants of the third portion 136 can be substantially uniform (FIG. 4C) or non-uniform (FIG. 4D).

The patterns of the mask layer 240 of the aforementioned embodiments are illustrative, and should not limit the claimed scope of the present disclosure. An embodiment falls within the claimed scope as long as the concentration of the dopants of the doped layer 130′ varies along the lateral direction D, such that the Cgs and Cgd can be adjusted.

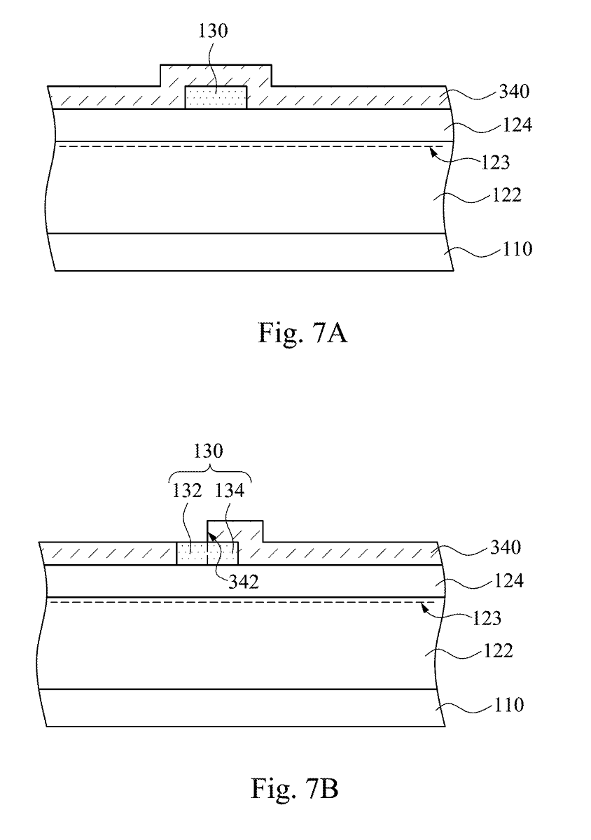

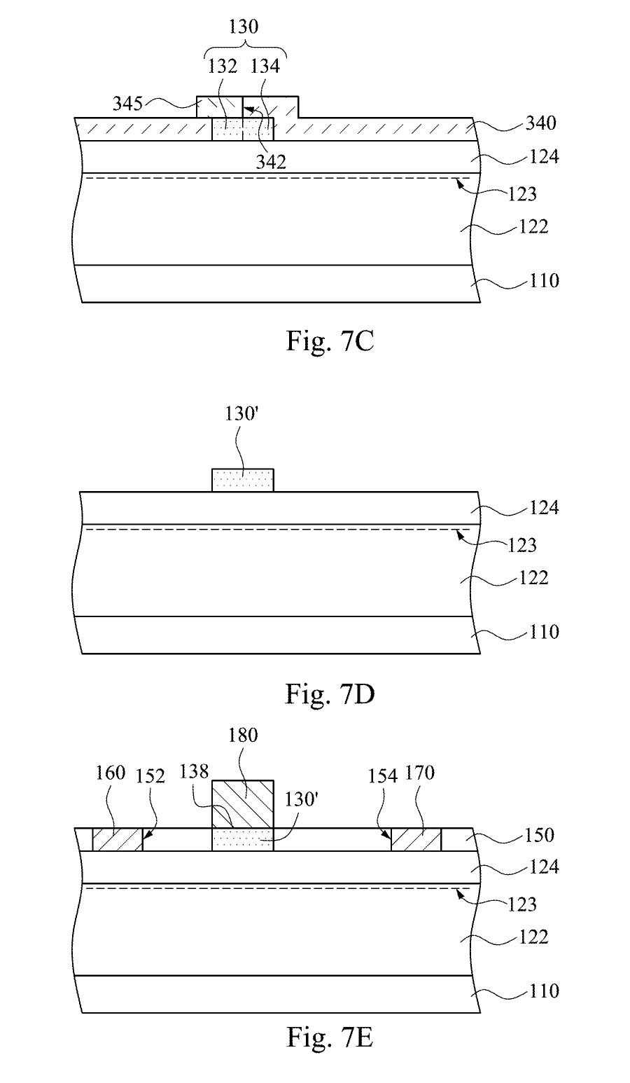

FIGS. 7A to 7E are cross-sectional views of a method for manufacturing a semiconductor device at different stages according to some embodiments of the present disclosure. Reference is made to FIG. 7A. The manufacturing process of FIG. 1A is performed in advance. Since the relevant manufacturing details are all the same as FIG. 1A, and, therefore, a description in this regard will not be repeated hereinafter. Subsequently, a mask layer 340 is formed to cover the semiconductor layer 130. In some embodiments, the mask layer 340 is made of photoresist, SiO₂, or SiNₓ.

Reference is made to FIG. 7B. The mask layer 340 is patterned to form at least one opening 342 to expose at least a portion of the semiconductor layer 130. For example, in FIG. 7B, the opening 342 of the mask layer 340 exposes the first portion 132 of the semiconductor layer 130. The mask layer 340 can be patterned by using a lithography process. Alternatively, the lithography process is implemented or replaced by other methods, such as maskless lithography, electron-beam writing, or ion-beam writing. In some embodiments, the lithography process implements an etching process, such as a dry etching, wet etching, other etching method, or combinations thereof.

Reference is made to FIG. 7C. A dopant material 345 is formed (or deposited) in the opening 342 of the mask layer 340. That is, the dopant material 345 disposed on the first portion 132 of the semiconductor layer 130. In some embodiments, the dopant material 345 may be made of C or metal, such as Mg, Ca, Fe, Cr, V, Mn, Be, or combinations thereof.

An annealing process is performed to the semiconductor layer 130. The elements of the dopant material 345 diffuse into the semiconductor layer 130 during the annealing process to form the doped layer 130′. Since the dopant material 345 covers the first portion 132 while the mask layer 340 covers the second portion 134, the concentration of the dopants of the doped layer 130′ varies along the lateral direction D. For example, the concentration curve may be depicted as shown in FIGS. 2A or 2B.

Reference is made to FIG. 7D. The mask layer 340 and the dopant material 345 (see FIGS. 7D) are removed. In some embodiments, the removing process implements an etching process, such as a dry etching, wet etching, other etching method, or combinations thereof.

Reference is made to FIG. 7E. A passivation layer 150 is formed to cover the doped layer 130′ and the barrier layer 124. The passivation layer 150 is patterned to form a first opening 152 and a second opening 154. A source electrode 160 and a drain electrode 170 are respectively formed in the first opening 152 and the second opening 154. The passivation layer 150 is further patterned to expose the top surface 138 of the doped layer 130′. A gate electrode 180 is formed on the doped layer 130′. Since the abovementioned processes are similar to the processes shown in FIGS. 1F to 1H, a description in this regard will not be repeated hereinafter.

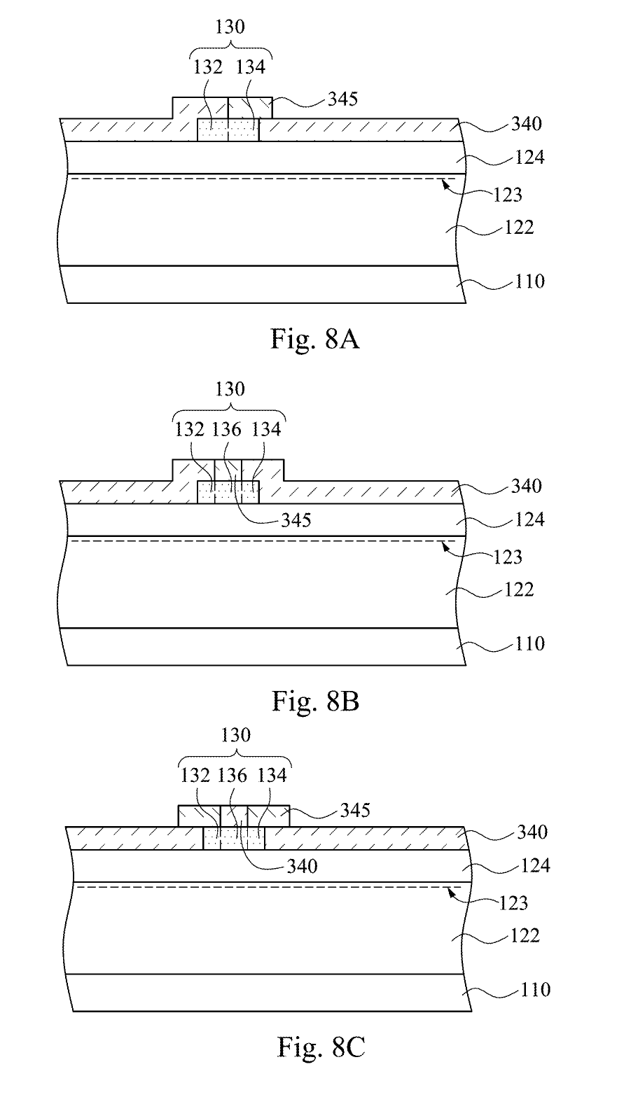

Moreover, in some other embodiments, the mask layer 340 and the dopant material 345 (see FIG. 7C) have different patterns to form the doped layer 130′ with different concentration distributions of the dopants. FIGS. 8A to 8C are cross-sectional views of the semiconductor devices at the stage of FIG. 7C according to some embodiments. In FIG. 8A, the dopant material 345 covers the second portion 134 of the semiconductor layer 130 and the mask layer 340 covers the first portion 132 of the semiconductor layer 130. After the annealing process, the concentration of the dopants of the doped layer can be depicted as shown in FIG. 4A or 4B. In FIG. 8B, the dopant material 345 covers the third portion 136 of the semiconductor layer 130 and the mask layer 340 covers the first portion 132 and the second portion 134 of the semiconductor layer 130. After the annealing process, the concentration of the dopants of the doped layer can be depicted as shown in FIG. 4C or 4D. The concentration of the dopants of the third portion 136 can be substantially uniform (FIG. 4C) or non-uniform (FIG. 4D). In FIG. 8C, the dopant material 345 covers the first portion 132 and the second portion 134 of the semiconductor layer 130 and the mask layer 340 covers the third portion 136 of the semiconductor layer 130. After the annealing process, the concentration of the dopants of the doped layer can be depicted as shown in FIG. 4E or 4F. The concentration of the dopants of the third portion 136 can be substantially uniform (FIG. 4E) or non-uniform (FIG. 4F).

The patterns of the mask layer 340 and the dopant material 345 of the aforementioned embodiments are illustrative, and should not limit the claimed scope of the present disclosure. An embodiment falls within the claimed scope as long as the concentration of the dopants of the doped layer 130′ varies along the lateral direction D, such that the Cgs and Cgd can be adjusted.

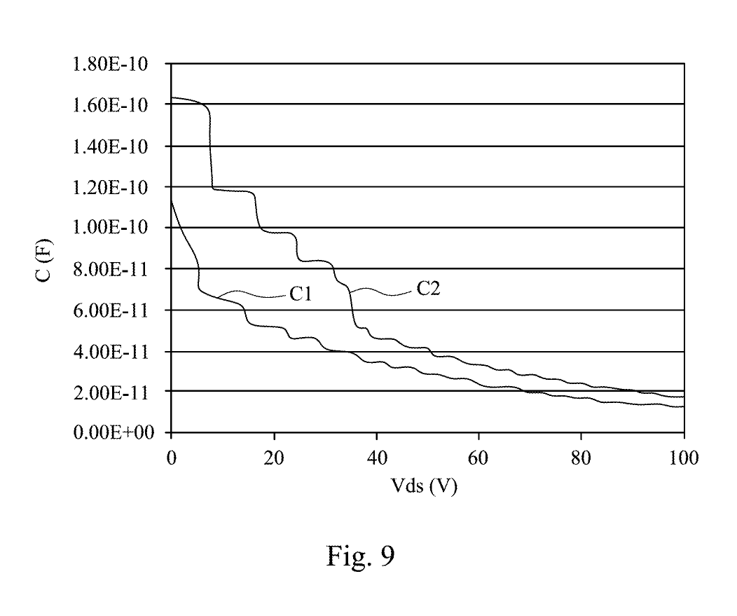

FIG. 9 is a graph of simulated gate-drain capacitances versus source-drain voltage (Vsd) of semiconductor device having a uniform and non-uniform doped layer. The curve C1 in FIG. 9 represents the gate-drain capacitance of the embodiment of semiconductor device in FIG. 1H, and the curve C2 in FIG. 9 represents the gate-drain capacitance of a semiconductor device having a uniform doped layer. As shown in FIG. 9, the gate-drain capacitance was reduced when the doped layer of the semiconductor device have non-uniform doping distribution (i.e., the concentration of the dopants varies along the lateral direction). That is, the gate-drain capacitance of the semiconductor device can be adjusted by forming the doped layer as mentioned in the aforementioned embodiments.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure covers modifications and variations of this disclosure provided they fall within the scope of the following claims.

1. A semiconductor device comprising:
a substrate;
a plurality of III-nitride semiconductor layers disposed on the substrate, and a two dimensional electron gas (2DEG) channel formed in the III-nitride semiconductor layers;
a source electrode, a gate electrode, and a drain electrode disposed on the III-nitride semiconductor layers, the gate electrode being located between the source electrode and the drain electrode, the source electrode and the drain electrode are electrically connected to the 2DEG channel, and a lateral direction is defined from the source electrode to the drain electrode; and
an annealed doped layer disposed between the gate electrode and the III-nitride semiconductor layers, wherein the annealed doped layer comprises a plurality of dopants, and a concentration of the dopants of the annealed doped layer varies along the lateral direction.

2. The semiconductor device of claim 1, wherein the concentration of the dopants decreases along the lateral direction.

3. The semiconductor device of claim 1, wherein the concentration of the dopants increases along the lateral direction.

4. The semiconductor device of claim 1, wherein the annealed doped layer comprises a first portion, a second portion, and a third portion arranged along the lateral direction, the third portion is disposed between the first portion and the second portion, and the concentration of the dopants of the third portion is higher than the concentration of the dopants of the first portion and the concentration of the dopants of the second portion.

5. The semiconductor device of claim 4, wherein the concentration of the dopants of the third portion is substantially uniform.

6. The semiconductor device of claim 1, wherein the annealed doped layer comprises a first portion, a second portion, and a third portion arranged along the lateral direction, the third portion is disposed between the first portion and the second portion, and the concentration of the dopants of the third portion is lower than the concentration of the dopants of the first portion and the concentration of the dopants of the second portion.

7. The semiconductor device of claim 6, wherein the concentration of the dopants of the third portion is substantially uniform.

8. The semiconductor device of claim 1, wherein the dopants of the doped layer comprise Mg, C, Ca, Fe, Cr, V, Mn, Be, or combinations thereof.

9. The semiconductor device of claim 1, wherein the annealed doped layer is made of InₓAl_{y}Ga_{1-x-y}N, wherein—x+y≦1.

10. A method for manufacturing a semiconductor device comprising:
forming a plurality of III-nitride semiconductor layers on a substrate;
forming a doped layer on the III-nitride semiconductor layers, wherein the forming the doped layer comprises an annealing process, the doped layer comprises a plurality of dopants, and a concentration of the dopants varies along a lateral direction;
forming a source electrode and a drain electrode on the III-nitride semiconductor layers, wherein the source electrode and the drain electrode are arranged along the lateral direction, and the doped layer is disposed between the source electrode and the drain electrode; and
forming a gate electrode on the doped layer.

11. The method of claim 10, wherein the forming the doped layer comprises:
forming a semiconductor layer on the III-nitride semiconductor layers;
forming a mask layer to cover the semiconductor layer;
patterning the mask layer to expose at least a portion of the semiconductor layer; and
implanting the dopants into the semiconductor layer to form the doped layer.

12. The method of claim 11, further comprising:
removing the patterned mask layer after the implantation is performed; and
annealing the doped layer by the annealing process.

13. The method of claim 11, wherein the mask layer is made of photoresist, SiO₂, SiNₓ, or metal.

14. The method of claim 10, wherein the forming the doped layer comprises:
forming a semiconductor layer on the III-nitride semiconductor layers;
forming a mask layer to cover the semiconductor layer;
patterning the mask layer to expose at least a portion of the semiconductor layer; and
annealing the semiconductor layer to form the doped layer by the annealing process.

15. The method of claim 14, wherein the mask layer is made of metal.

16. The method of claim 10, wherein the forming the doped layer comprises:
forming a semiconductor layer on the III-nitride semiconductor layers;
forming a mask layer to cover the semiconductor layer;
patterning the mask layer to form at least one opening to expose at least a portion of the semiconductor layer;
forming a doping material in the opening; and
annealing the semiconductor layer to diffuse the dopants to form the doped layer by the annealing process.

17. The method of claim 16, wherein the dopant material is made of metal.

18. The method of claim 10, wherein the dopants of the doped layer comprise Mg, C, Ca, Fe, Cr, V, Mn, Be, or combinations thereof.

19. The method of claim 10, wherein the doped layer is made of InₓAl_{y}Ga_{1-x-y}N, wherein x+y≦1.

20. The method of claim 10, further comprising:
forming a passivation layer on the III-nitride semiconductor layers to cover the doped layer; and
removing a portion of the passivation layer on the doped layer.
